(19) United States
(12) Patent Application Publication
(10) Pub. No.: US 2024/0096889 A1
(43) Pub. Date: Mar. 21, 2024

(54) INTEGRATED CIRCUIT DEVICES INCLUDING STACKED TRANSISTORS AND METHODS OF FORMING THE SAME

(71) Applicant: Samsung Electronics Co., Ltd., Suwon-si (KR)

(72) Inventors: Seung Min Song, Halfmoon, NY (US); Seungchan Yun, Waterford, NY (US); Kang-ill Seo, Springfield, VA (US)

(21) Appl. No.: 18/173,847

(22) Filed: Feb. 24, 2023

Related U.S. Application Data
(60) Provisional application No. 63/376,590, filed on Sep. 21, 2022.

(51) Int. Cl. H01L 27/092; H01L 21/822; H01L 21/8238; H01L 29/06; H01L 29/423; H01L 29/66; H01L 29/775

(52) U.S. Cl. CPC H01L 27/0922; H01L 21/8221; H01L 21/823807; H01L 21/823814; H01L 21/823878; H01L 29/0673; H01L 29/42392; H01L 29/66439; H01L 29/775

(57) ABSTRACT

Integrated circuit devices may include a first upper channel region on a substrate, a first lower channel region between the substrate and the first upper channel region, a first intergate insulator that is between the first lower channel region and the first upper channel region and includes a lower portion and an upper portion, an upper gate electrode, and a lower gate electrode between the substrate and the upper gate electrode. The first upper channel region and the upper portion of the first intergate insulator may be in the upper gate electrode. The first lower channel region and the lower portion of the first intergate insulator are in the lower gate electrode.

### CROSS-REFERENCE TO RELATED APPLICATION

This application claims priority to U.S. Provisional Application Ser. No. 63/376,590 entitled THICK MDI FORMATION BY USING WAFER BONDING TECHNOLOGY IN MONOLITHIC 3D-SFET, filed in the USPTO on Sep. 21, 2022, the disclosure of which is hereby incorporated by reference herein in its entirety.

### BACKGROUND

The present disclosure generally relates to the field of integrated circuit devices and, more particularly, to three-dimensional integrated circuit devices that include stacked transistors.

Various structures of an integrated circuit device including stacked transistors and methods of forming the same have been proposed for secure isolation between elements of stacked transistors (e.g., stacked source/drain regions or stacked gate electrodes).

### SUMMARY

An integrated circuit devices according to some embodiments may include a first upper channel region on a substrate, a first lower channel region between the substrate and the first upper channel region, a first intergate insulator that is between the first lower channel region and the first upper channel region and includes a lower portion and an upper portion, an upper gate electrode, and a lower gate electrode between the substrate and the upper gate electrode. The first upper channel region and the upper portion of the first intergate insulator may be in the upper gate electrode. The first lower channel region and the lower portion of the first intergate insulator are in the lower gate electrode.

An integrated circuit devices according to some embodiments may include an upper transistor that is on a substrate and includes an upper channel region and an upper source/drain region contacting a side surface of the upper channel region, a lower transistor that is between the substrate and the upper transistor and the lower transistor includes a lower channel region and a lower source/drain region contacting a side surface of the lower channel region, and an intergate insulator between the upper channel region and the lower channel region. An entirety of the intergate insulator overlaps the lower channel region.

A method of forming an integrated circuit devices according to some embodiments may include providing a lower stack comprising a lower substrate, a lower intergate insulator layer on the lower substrate and a lower channel layer between the lower substrate and the lower intergate insulator layer. The lower intergate insulator layer may include a lower surface facing the lower substrate and an upper surface opposite the lower surface of the lower intergate insulator layer. The methods may also include providing an upper stack comprising an upper substrate, an upper intergate insulator layer on the upper substrate and an upper channel layer between the upper substrate and the upper intergate insulator layer. The upper intergate insulator layer may include a lower surface facing the upper substrate and an upper surface opposite the lower surface of the upper intergate insulator layer. The methods may further include forming a merged stack by attaching the upper surface of the upper intergate insulator layer to the upper surface of the lower intergate insulator layer, forming a preliminary channel stack by patterning the merged stack, wherein the preliminary channel stack extends in a first direction and forming a channel stack by patterning the preliminary channel stack. The channel stack may include an upper channel region, a lower channel region and an intergate insulator that is between the lower channel region and the upper channel region. Additionally, the methods may include forming a lower source/drain region contacting a side surface of the lower channel region and forming an upper source/drain region contacting a side surface of the upper channel region.

### BRIEF DESCRIPTION OF THE DRAWINGS

FIG. 1 is a layout of an integrated circuit device according to some embodiments.

FIGS. 2 and 3 are cross-sectional views of an integrated circuit device taken along the line A-A′ and the line B-B′, respectively, in FIG. 1 according to some embodiments.

FIG. 4 is an enlarged view of the first region R1 in FIG. 3 according to some embodiments.

FIG. 5 is a cross-sectional view of an integrated circuit device taken along the line B-B′ in FIG. 1 according to some embodiments.

FIG. 6 is a cross-sectional view of an integrated circuit device taken along the line A-A′ in FIG. 1 according to some embodiments.

FIG. 7 is an enlarged view of the second region R2 in FIG. 6 according to some embodiments.

FIG. 8 is a cross-sectional view of an integrated circuit device taken along the line B-B′ in FIG. 1 according to some embodiments.

FIG. 9 is a cross-sectional view of an integrated circuit device taken along the line B-B′ in FIG. 1 according to some embodiments.

FIG. 10 is a flow chart of a method of forming an integrated circuit device according to some embodiments.

FIGS. 11 through 22 are cross-sectional views illustrating a method of forming an integrated circuit device according to some embodiments.

FIGS. 23 through 28 are cross-sectional views illustrating a method of forming an integrated circuit device according to some embodiments.

### DETAILED DESCRIPTION

An integrated circuit device including stacked transistors may include an intergate insulator between the stacked transistors. A thick intergate insulator may be desirable for fabrication processes and/or electrical isolation between elements of stacked transistors. When an intergate insulator is formed using a sacrificial layer including a semiconductor material, a thickness of the intergate insulator may be limited by a material and/or a method of forming the sacrificial layer.

According to some embodiments, an intergate insulator may be formed by merging two insulating layers of lower and upper stack structures without using a sacrificial layer. A thickness of the intergate insulator may be determined by respective thicknesses of the two insulating layers and can be increased to a desired thickness by adjusting the thicknesses of the two insulating layers.

Example embodiments will be described in greater detail with reference to the attached figures.

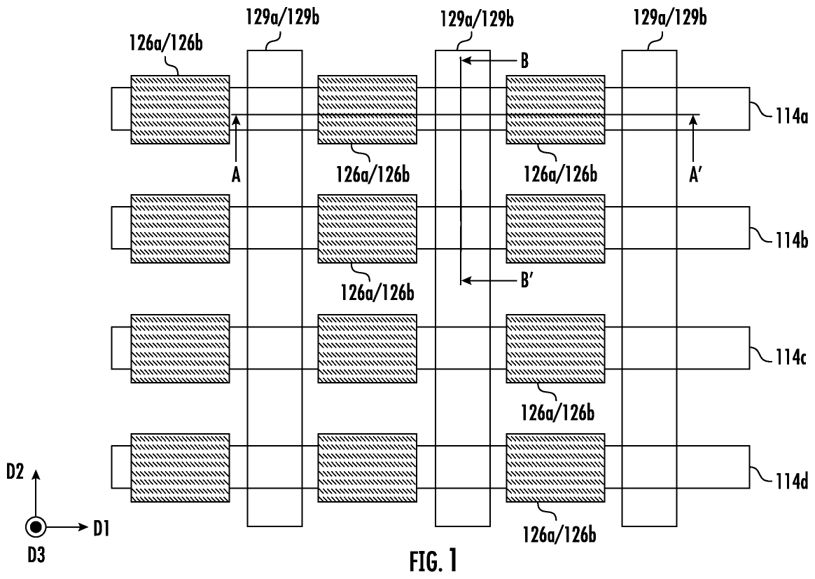

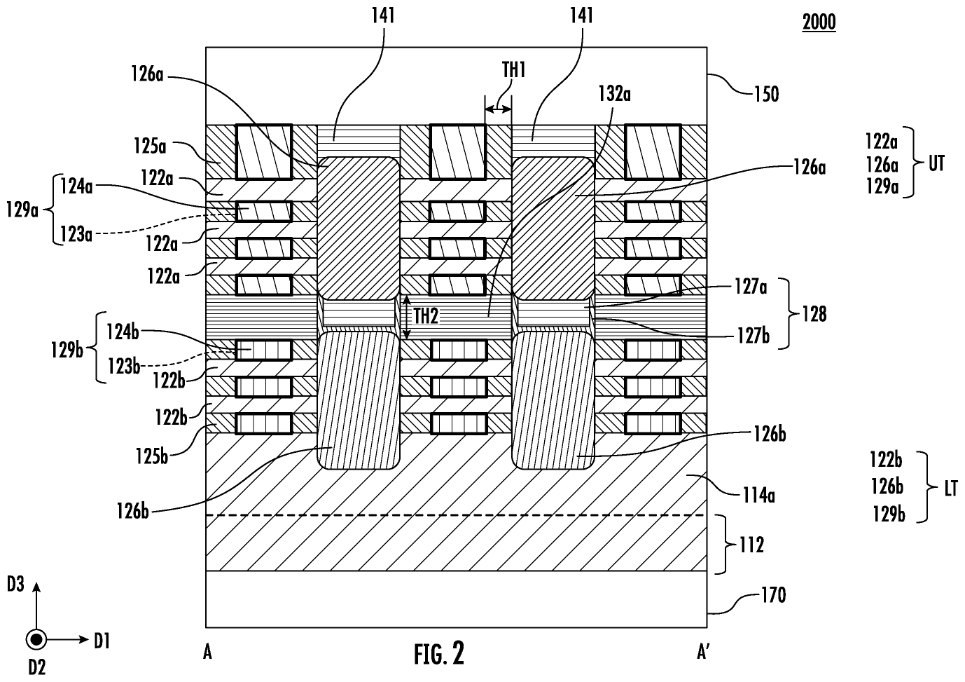

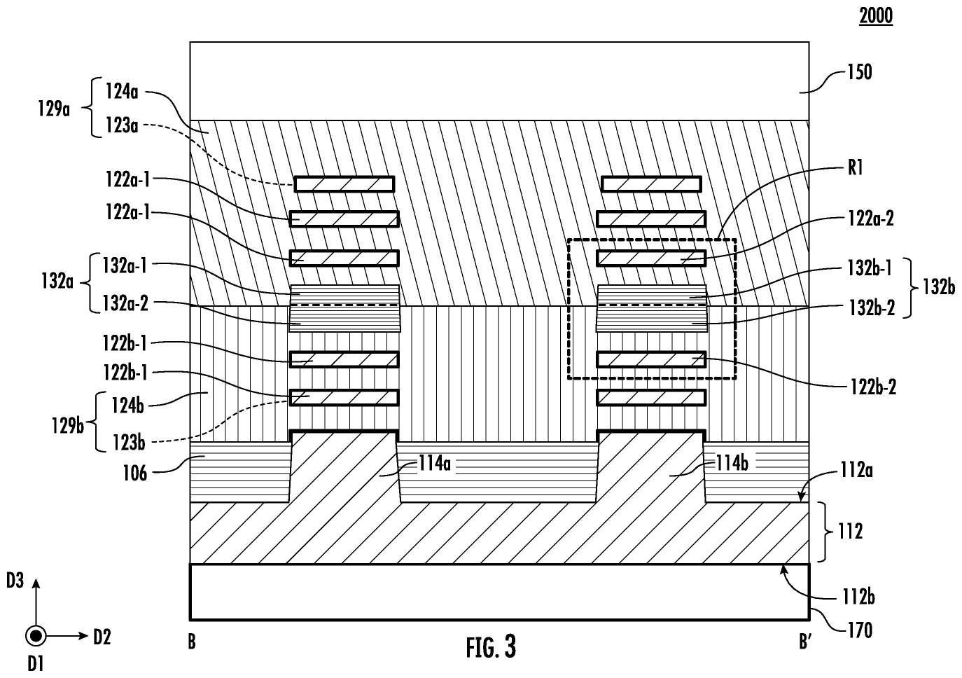

FIG. 1 is a layout of an integrated circuit device according to some embodiments. FIGS. 2 and 3 are cross-sectional views of a first integrated circuit device 2000 taken along the line A-A′ and the line B-B′, respectively, in FIG. 1 according to some embodiments.

Referring to FIGS. 1, 2 and 3, the first integrated circuit device 2000 may include transistor stacks provided on a substrate 112. Each of the transistor stacks may include an upper transistor UT and a lower transistor LT that is provided between the substrate 112 and the upper transistor UT. The substrate 112 may include an upper surface 112a and a lower surface 112b opposite the upper surface 112a. The upper surface 112a and the lower surface 112b may be parallel to each other. As used herein, “a lower X” may refer to the X that is closer to a substrate (e.g., the substrate 112) than an upper X.

First, second, third and fourth semiconductor regions 114a, 114b, 114c, 114d (also referred to as first, second, third and fourth active regions) may be provided on the substrate 112. The first second, third and fourth semiconductor regions 114a, 114b, 114c, 114d may extend in a first direction D1 (also referred to as a first horizontal direction) and may be spaced apart from each other in a second direction D2 (also referred to as a second horizontal direction). As used herein, “an element A extends in a direction X” (or similar language) may mean that the element A extends longitudinally in the direction X. The first direction D1 may be perpendicular to the second direction D2.

The first second, third and fourth semiconductor regions 114a, 114b, 114c, 114d may protrude from the upper surface 112a of the substrate 112 in a third direction D3 (also referred to as a vertical direction). The third direction D3 may be perpendicular to the first direction D1 and the second direction D2. In some embodiments, the third direction D3 may be perpendicular to the upper surface 112a and the lower surface 112b of the substrate 112.

A trench isolation layer 106 may be provided on the substrate 112. Adjacent semiconductor regions (e.g., the first and second semiconductor regions 114a and 114b) may be separated from each other by a portion of the trench isolation layer 106.

The substrate 112 may include one or more semiconductor materials, for example, Si, Ge, SiGe, GaP, GaAs, SiC, SiGeC and/or InP or may include insulating material, for example, silicon oxide, silicon oxynitride, silicon nitride, silicon carbonitride, silicon boron nitride and/or a low-k material. In some embodiments, the substrate 112 may be a bulk substrate (e.g., a bulk silicon substrate) or a semiconductor on insulator (SOI) substrate. For example, the substrate 112 may be a silicon wafer or may be an insulating layer.

Each of the first, second, third and fourth semiconductor regions 114a, 114b, 114c, 114d may be, for example, a portion of the substrate 112 or may be a layer formed using the substrate 112 as a seed layer through, for example, an epitaxial growth process. Each of the first, second, third and fourth semiconductor regions 114a, 114b, 114c, 114d may include semiconductor material(s), for example, Si, Ge, SiGe, GaP, GaAs, SiC, SiGeC and/or InP.

The trench isolation layer 106 may include an insulating material(s) (e.g., silicon oxide, silicon oxynitride, silicon nitride, silicon carbonitride and/or a low-k material). The low-k material may include, for example, fluorine-doped silicon oxide, organosilicate glass, carbon-doped oxide, porous silicon dioxide, porous organosilicate glass, spin-on organic polymeric dielectrics and/or spin-on silicon based polymeric dielectric.

The lower transistor LT may include lower channel regions 122b that may be stacked on the substrate 112 in the third direction D3 and may overlap each other in the third direction D3. As used herein, “an element A and an element B that overlap each other in a direction X” (or similar language) may mean that at least one line can be drawn that intersects both elements A and B and extends in the direction X. The lower channel regions 122b may be stacked on the semiconductor region (e.g., the first semiconductor region 114a). The lower channel region 122b may include opposing side surfaces that are spaced apart from each other in the first direction D1, and the lower transistor LT may include a pair of lower source/drain regions 126b respectively on those opposing side surfaces of the lower channel region 122b. The pair of lower source/drain regions 126b may contact those opposing side surfaces of the lower channel region 122b, respectively.

The lower transistor LT may also include a lower gate structure 129b that may include a lower gate insulator 123b and a lower gate electrode 124b. The lower gate electrode 124b may extend in the second direction D2 and may traverse the semiconductor region 114 (e.g., the first, second, third and/or fourth semiconductor regions 114a, 114b, 114c and/or 114d). A portion of the lower channel region 122b may be in the lower gate electrode 124b, and the lower gate insulator 123b may separate the lower channel region 122b from the lower gate electrode 124b. The lower channel region 122b may extend through the lower gate electrode 124b in the first direction D1 and may contact the lower gate insulator 123b.

The upper transistor UT may include upper channel regions 122a that may be stacked on the substrate 112 in the third direction D3 and may overlap each other in the third direction D3. The upper channel regions 122a may also overlap lower channel region 122b in the third direction D3. The upper channel region 122a may include opposing side surfaces that are spaced apart from each other in the first direction D1, and the upper transistor UT may include a pair of upper source/drain regions 126a respectively on those opposing side surfaces of the upper channel region 122a. The pair of upper source/drain regions 126a may contact those opposing side surfaces of the upper channel region 122a, respectively.

The upper transistor UT may also include an upper gate structure 129a that may include an upper gate insulator 123a and an upper gate electrode 124a. The upper gate electrode 124a may extend in the second direction D2 and may traverse the semiconductor region 114 (e.g., the first, second, third and/or fourth semiconductor regions 114a, 114b, 114c and/or 114d). A portion of the upper channel region 122a may be in the upper gate electrode 124a, and the upper gate insulator 123a may separate the upper channel region 122a from the upper gate electrode 124a. The upper channel region 122a may extend through the upper gate electrode 124a in the first direction D1 and may contact the upper gate insulator 123a.

The lower and upper channel regions 122b and 122a may include, for example, semiconductor material(s) (e.g., Si, Ge, SiGe, GaP, GaAs, SiC, SiGeC and/or InP). In some embodiments, the lower channel regions 122b may include a material different from the upper channel regions 122a. In some embodiments, each of the lower and upper channel regions 122b and 122a may be a nanosheet that may have a thickness in a range of from 1 nm to 100 nm in the third direction D3 or may be a nanowire that may have a circular cross-section with a diameter in a range of from 1 nm to 100 nm.

The lower and upper gate insulators 123b and 123a may include, for example, a silicon oxide layer and/or a high-k material layer. The high-k material layer may include, for example, Al₂O₃, HfO₂, ZrO₂, HfZrO₄, TiO₂, Sc₂O₃ Y₂O₃, La₂O₃, Lu₂O₃, Nb₂O₅ and/or Ta₂O₅. The lower and upper gate electrodes 124b and 124a may include, for example, a metallic layer that includes, for example W, Al, Cu, Mo, Co and/or Ru and may additionally include work function layer(s) (e.g., a TiN layer, a TaN layer, a TiAl layer, a TiC layer, a TiAlC layer, a TiAlN layer and/or a WN layer).

In some embodiments, a lower insulating spacer 125b (also referred to as a lower gate spacer or a lower inner gate spacer) may be provided between the lower gate structure 129b and the lower source/drain region 126b, and an upper insulating spacer 125a (also referred to as an upper gate spacer or an upper inner gate spacer) may be provided between the upper gate structure 129a and the upper source/drain region 126a. The lower insulating spacer 125b may separate the lower gate structure 129b and the lower source/drain region 126b from each other, and the upper insulating spacer 125a may separate the upper gate structure 129a and the upper source/drain region 126a from each other.

Each of the lower insulating spacer 125b and the upper insulating spacer 125a may include, for example, silicon oxide, silicon oxynitride, silicon nitride, silicon carbonitride and/or a low-k material. In some embodiments, each of the lower insulating spacer 125b and the upper insulating spacer 125a may have a first thickness TH1 in the first direction D1. In some embodiments, each of the of the lower insulating spacer 125b and the upper insulating spacer 125a may have a thickness in the first direction D1 that is non-uniform and changes along the third direction D3, and the first thickness TH1 may be a thickest thickness of the lower insulating spacer 125b and the upper insulating spacer 125a in the first direction D1. For example, the first thickness TH1 may be in a range of from 1 nm to 10 nm (e.g., from 2 nm to 8 nm, about 4 nm or about 5 nm).

In some embodiments, the lower transistor LT and the upper transistor UT may have different conductivity types, and the transistor stack including the lower transistor LT and the upper transistor UT may be a complementary metal-oxide-semiconductor (CMOS).

Still referring to FIGS. 1 through 3, the first integrated circuit device 2000 may further include an intergate insulator 132 that is between the lower gate electrode 124b and the upper gate electrode 124a. The first integrated circuit device 2000 may include multiple intergate insulators 132 (e.g., first and second intergate insulators 132a and 132b) that are spaced apart from each other in the first direction D1 and the second direction D2. The upper channel region 122a (e.g., a first upper channel region 122a-1 or a second upper channel region 122a-2) may overlap the intergate insulator 132 and the lower channel region 122b (e.g., a first lower channel region 122b-1 or a second lower channel region 122b-2) in the third direction D3, and the upper gate electrode 124a (e.g., a first upper gate electrode 124a-1 or a second upper gate electrode 124a-2) may overlap the intergate insulator 132 and the lower gate electrode 124b (e.g., a first lower gate electrode 124b-1 or a second lower gate electrode 124b-2) in the third direction D3.

The intergate insulator 132 may have a second thickness TH2 in the third direction D3. The second thickness TH2 may be thicker than the first thickness TH1 of the lower insulating spacer 125b and the upper insulating spacer 125a. The second thickness TH2 may be at least two times the first thickness TH1 of the lower insulating spacer 125b and the upper insulating spacer 125a. For example, the second thickness TH2 may be in a range of from 15 nm to 40 nm (e.g., from 20 nm to 40 nm or about 25 nm). In some embodiments, the second thickness TH2 may be thicker than 20 nm. In some embodiments, the intergate insulator 132 may include a material different from the lower insulating spacer 125b and the upper insulating spacer 125a.

Referring to FIG. 2, in some embodiments, an entirety of the intergate insulator 132 may overlap the lower channel region 122b in the third direction D3. The upper channel regions 122a may have an equal width in the first direction D1 and may include respective first side surfaces that face the same direction. Those first side surfaces of the upper channel regions 122a may be in the same plane and may be aligned along the third direction D3. The lower channel regions 122b may have an equal width in the first direction D1 and may include respective first side surfaces that face the same direction. Those first side surfaces of the lower channel regions 122b may be in the same plane and may be aligned along the third direction D3. The intergate insulator 132 includes a first side surface that may be aligned with the first side surfaces of the lower and upper channel regions 122b and 122a along the third direction D3 and may be in the same plane with the first side surfaces of the lower and upper channel regions 122b and 122a. An interlayer insulator 141 may be provided on the upper source/drain region 126a. Each of the intergate insulator 132 and the interlayer insulator 141 may include, for example, silicon oxide, silicon oxynitride, silicon nitride, silicon carbonitride, silicon boron nitride and/or a low-k material.

A source/drain insulator 128 may be provided between the lower source/drain region 126b and the upper source/drain region 126a. The source/drain insulator 128 may contact a side surface of the intergate insulator 132 and may include a material different from the intergate insulator 132. The source/drain insulator 128 may include an outer layer 127b that contacts a side surface of the intergate insulator 132. The outer layer 127b may include a material different from the intergate insulator 132 and may include, for example, nitrogen. The source/drain insulator 128 may also include an inner layer 127a. The outer layer 127b may contact opposing side surfaces and/or a lower surface of the inner layer 127a. The inner layer 127a may include a material different from the outer layer 127b. In some embodiments, the source/drain insulator 128 may have a width in the first direction D1, which may be equal to a width of the lower source/drain region 126b in the first direction D1 and/or a width of the upper source/drain region 126a in the first direction D1. For example, the inner layer 127a may include, silicon oxide, silicon oxynitride, silicon nitride, silicon carbonitride, silicon boron nitride and/or a low-k material, and the outer layer 127b may include silicon carbonitride, aluminum nitride, silicon oxynitride and/or silicon nitride.

Referring to FIG. 3, the intergate insulator 132 may include a lower portion and an upper portion. For example, the first intergate insulator 132a may include an upper portion 132a-1 and a lower portion 132a-2, and the second intergate insulator 132b may include an upper portion 132b-1 and a lower portion 132b-2. The upper channel region 122a (e.g., the first upper channel region 122a-1 and the second upper channel region 122a-2) and the upper portion of the intergate insulator 132 (e.g., the upper portions 132a-1 and 132b-1) may be in the upper gate electrode 124a. In some embodiments, the upper gate electrode 124a may enclose the upper channel region 122a and may extend on an upper surface and a side surface of the upper portion (e.g., the upper portion 132a-1) of the intergate insulator 132. In some embodiments, the upper gate electrode 124a may contact the upper surface and the side surface of the upper portion of the intergate insulator 132. A portion of the upper gate electrode 124a may be provided between two adjacent intergate insulators 132 (e.g., the first and second intergate insulators 132a and 132b) and may separate those intergate insulators 132 from each other.

The lower channel region 122b (e.g., the first lower channel region 122b-1 and the second lower channel region 122b-2) and the lower portion (e.g., the lower portion 132a-2 and 132b-2) of the intergate insulator may be in the lower gate electrode 124b. In some embodiments, the lower gate electrode 124b may enclose the lower channel region 122b and may extend on a lower surface and a side surface of the lower portion (e.g., the lower portion 132a-2) of the intergate insulator 132. In some embodiments, the lower gate electrode 124b may contact the lower surface and the side surface of the lower portion of the intergate insulator 132. A portion of the lower gate electrode 124b may be provided between two adjacent intergate insulators 132 (e.g., the first and second intergate insulators 132a and 132b) and may separate those intergate insulators 132 from each other. Each of the first and second intergate insulators 132a and 132b may have a lower surface facing the substrate 112, and those lower surfaces of the first and second intergate insulator 132a and 132b may be equidistant from the substrate 112 (e.g., the upper surface 112a).

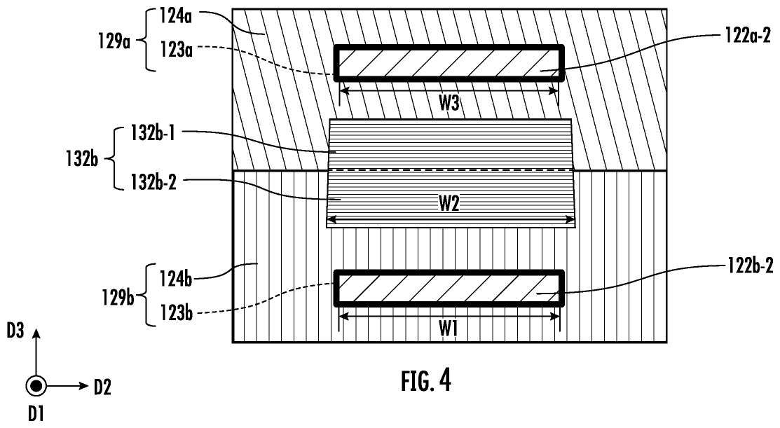

FIG. 4 is an enlarged view of the first region R1 in FIG. 3 according to some embodiments. Referring to FIGS. 3 and 4, the lower channel regions 122b (e.g., the second lower channel regions 122b-2) may include respective second side surfaces that face the same direction. Those second side surfaces of the lower channel regions 122b may be in the same plane. The lower channel regions 122b may have respective widths in the second direction D2, and those widths of the lower channel regions 122b may decrease as a distance from the substrate 112 increases. Accordingly, an uppermost lower channel region 122b of the lower channel regions 122b stacked in the third direction D3, which is farthest from the substrate 112, may have a narrowest width (e.g., a first width W1) in the second direction D2 among those lower channel regions 122b. As used herein, a width of an element may refer to a widest width of the element if the element has a non-uniform width.

The upper gate electrode 124a may contact an upper surface and opposing side surfaces of the upper portion of the intergate insulator 132 (e.g., the upper portion 132b-1 of the second intergate insulator 132b). The lower gate electrode 124b may contact a lower surface and opposing side surfaces of the lower portion of the intergate insulator 132 (e.g., the lower portion 132b-2 of the second intergate insulator 132b). The upper gate electrode 124a may include a lower surface that faces the substrate 112 and contacts the lower gate electrode 124b. The intergate insulator 132 may have a second width W2 in the second direction D2.

The upper channel regions 122a (e.g., the second upper channel regions 122a-2) may include respective second side surfaces that face the same direction. Those second side surfaces of the upper channel regions 122a may be in the same plane. Those second side surfaces of the upper channel regions 122a may be in the same plane with the second side surfaces of the lower channel regions 122b (e.g., the second lower channel regions 122b-2). The upper channel regions 122a may have respective widths in the second direction D2, and those widths of the upper channel regions 122a may decrease as a distance from the substrate 112 increases. Accordingly, a lowermost upper channel region 122a of the upper channel regions 122a stacked in the third direction D3, which is closest to the substrate 112, may have a widest width (e.g., a third width W3) in the second direction D2 among those upper channel regions 122a. In some embodiments, the third width W3 may be equal to or narrower than the first width W1 and the second width W2.

Still referring to FIGS. 3 and 4, an entirety of each of the upper channel regions 122a may overlap the lower channel regions 122b in the third direction D3. For example, an entirety of the lowermost upper channel region 122a may overlap the uppermost lower channel region 122b in the third direction D3.

Referring back to FIGS. 2 and 3, the first integrated circuit device 2000 may include an upper structure 150 that may include elements formed by the middle-of-line (MOL) portion and/or the back-end-of-line (BEOL) portion of device fabrication. The upper structure 150 may include conductive elements (e.g., a wire or a via plug) and insulating elements (e.g., an interlayer or a spacer). The conductive elements of the upper structure 150 may be electrically connected to, for example, the upper source/drain region 126a and/or the upper gate electrode 124a. The first integrated circuit device 2000 may further include a backside power distribution network (BSPDN) structure 170 provided on the lower surface 112b of the substrate 112. The BSPDN structure 170 may include conductive elements (e.g., a power line or a power via) and insulating elements (e.g., an interlayer or a spacer). The conductive elements of the BSPDN structure 170 may be electrically connected to, for example, the lower source/drain region 126b and/or the upper source/drain region 126a.

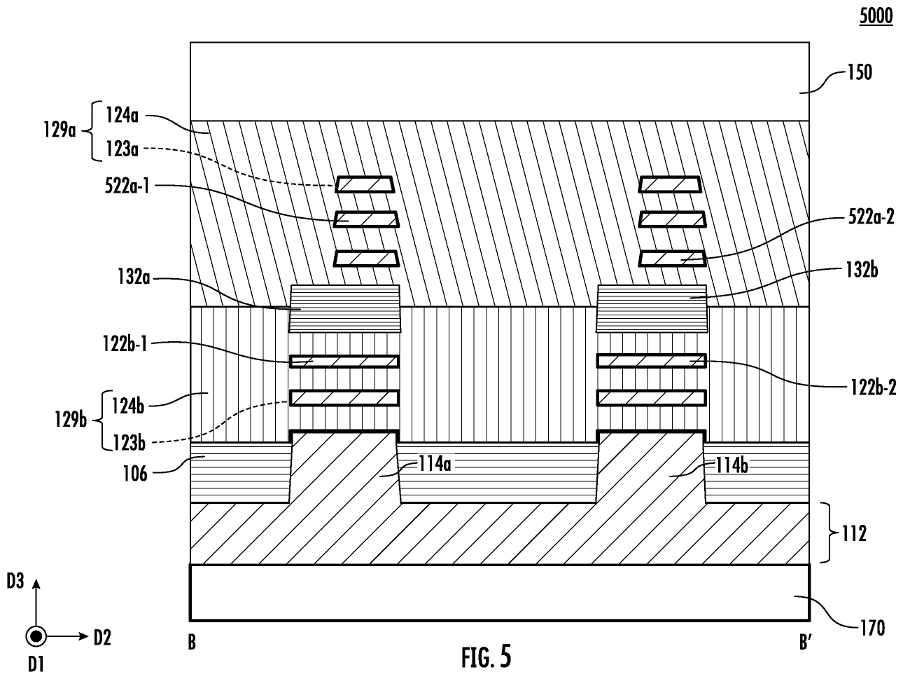

FIG. 5 is a cross-sectional view of a second integrated circuit device 5000 taken along the line B-B′ in FIG. 1 according to some embodiments. The second integrated circuit device 5000 may be similar to the first integrated circuit device 2000. The second integrated circuit device 5000 may include first upper channel regions 522a-1 including respective third side surfaces, and the first lower channel regions 122b-1 may include respective third side surfaces. The third side surfaces of the first upper channel regions 522a-1 and the third side surfaces of the first lower channel regions 122b-1 face the same direction. The second integrated circuit device 5000 may be different from the first integrated circuit device 2000, in that the third side surfaces of the first upper channel regions 522a-1 may not be in the same plane with the third side surfaces of the first lower channel regions 122b-1. A cross-sectional view of the second integrated circuit device 5000 taken along the line A-A′ in FIG. 1 may be similar to that illustrated in FIG. 2. The first and second upper channel regions 522a-1 and 522a-2 may include a material the same as or similar to the upper channel regions 122a of the first integrated circuit device 2000.

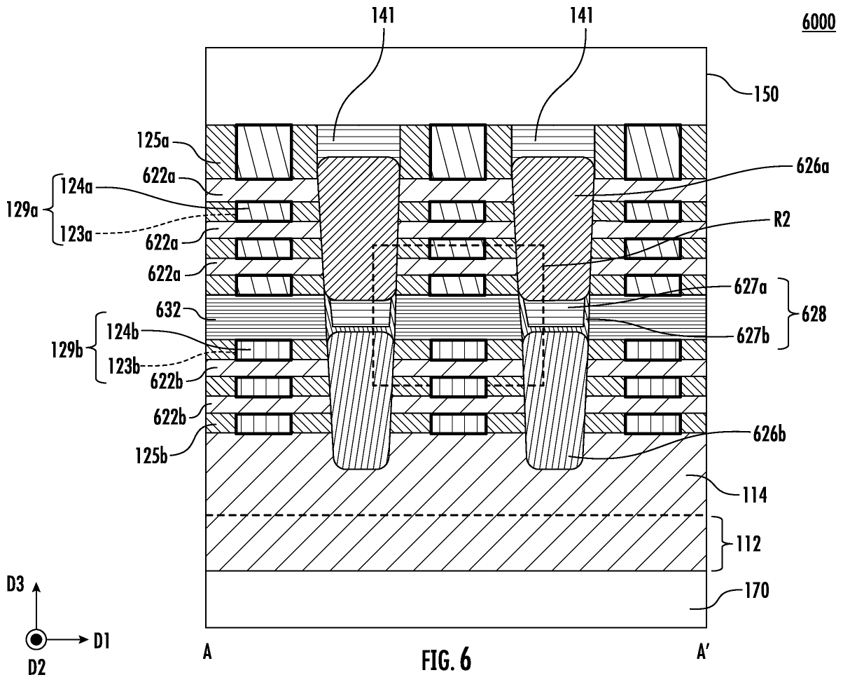

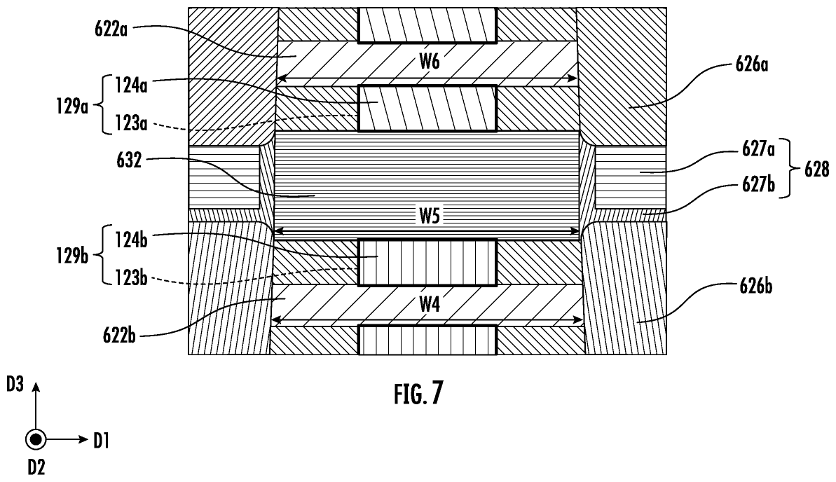

FIG. 6 is a cross-sectional view of a third integrated circuit device 6000 taken along the line A-A′ in FIG. 1 according to some embodiments, and FIG. 7 is an enlarged view of the second region R2 in FIG. 6 according to some embodiments. Referring to FIGS. 6 and 7, the third integrated circuit device 6000 may be similar to the first integrated circuit device 2000. The third integrated circuit device 6000 may be different from the first integrated circuit device 2000, in that several elements (e.g., an upper source/drain region 626a and an upper channel region 622a) may have a width in the first direction D1 changing along the third direction D3.

The upper channel regions 622a may include respective fourth side surfaces that face the same direction. Those fourth side surfaces of the upper channel regions 622a may be in the same plane. Lower channel regions 622b include respective fourth side surfaces that face the same direction. Those fourth side surfaces of the lower channel regions 622b may be in the same plane. An intergate insulator 632 may include a fourth side surface that is in the same plane with the fourth side surfaces of the lower and upper channel regions 622b and 622a.

The lower and upper channel regions 622b and 622a and the intergate insulator 632 may have respective widths in the first direction D1 decreasing as a distance from the substrate 112 increases. Accordingly, an uppermost lower channel region 622b of the lower channel regions 622b stacked in the third direction D3 may have a narrowest width (e.g., a fourth width W4) in the first direction D1 among those lower channel regions 622b. Further, a lowermost upper channel region 622a of the upper channel regions 622a stacked in the third direction D3 may have a widest width (e.g., a sixth width W6) in the first direction D1 among those upper channel regions 622a. The intergate insulator 632 may have a fifth width W5 in first direction D1. The sixth width W6 may be narrower than the fifth width W5 and the fourth width W4, and the fifth width W5 may be narrower than the fourth width W4.

An upper source/drain region 626a, a lower source/drain region 626b and a source/drain insulator 628 may have respective widths in the first direction D1 increasing as a distance from the substrate 112 increases. The source/drain insulator 628 may include an inner layer 627a and an outer layer 627b that may extend on opposing side surfaces and/or a lower surface of the inner layer 627a. In some embodiments, the outer layer 627b may contact the opposing side surfaces and/or the lower surface of the inner layer 627a and may include a material different from the inner layer 627a and/or the intergate insulator 632. A cross-sectional view of the third integrated circuit device 6000 taken along the line B-B′ in FIG. 1 may be similar to that illustrated in FIG. 3. The lower channel region 622b, the upper channel region 622a, the inner layer 627a, the outer layer 627b, the intergate insulator 632, the lower source/drain region 626b and the upper source/drain region 626a may include materials the same as or similar to those of the lower channel region 122b, the upper channel region 122a, the inner layer 127a, the outer layer 127b, the intergate insulator 132, the lower source/drain region 126b and the upper source/drain region 126a of the first integrated circuit device 2000.

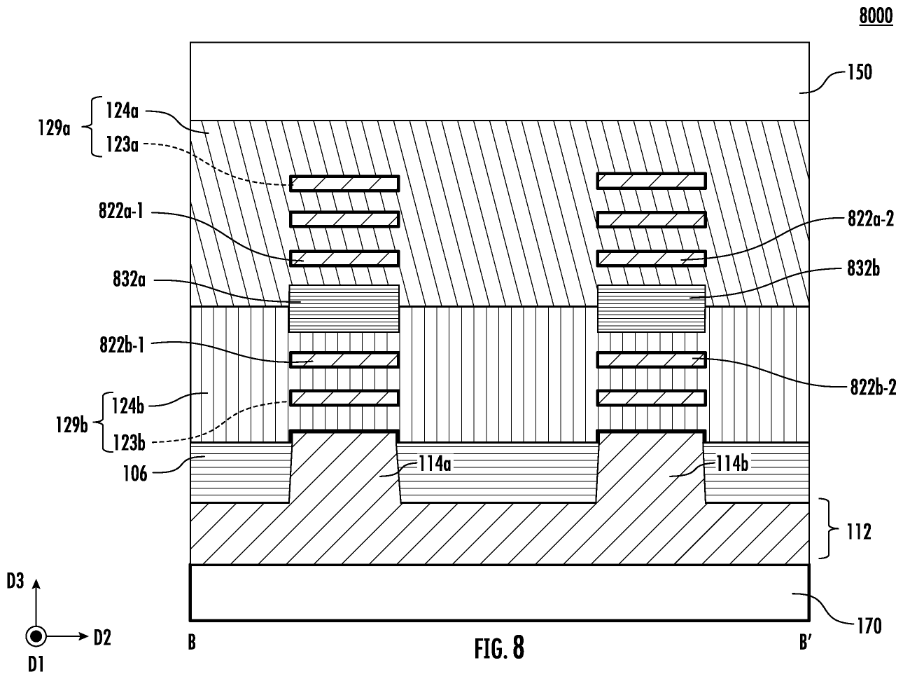

FIG. 8 is a cross-sectional view of a fourth integrated circuit device 8000 taken along the line B-B′ in FIG. 1 according to some embodiments. Referring to FIG. 8, the fourth integrated circuit device 8000 may be similar to the first integrated circuit device 2000. The fourth integrated circuit device 8000 may be different from the first integrated circuit device 2000, in that the fourth integrated circuit device 8000 may include multiple first upper channel regions 822a-1 that are stacked in the third direction D3 and have an equal width in the second direction D2, multiple first lower channel regions 822b-1 that are stacked in the third direction D3 and have an equal width in the second direction D2 and first and second intergate insulators 832a and 832b, each of which has a uniform width in the second direction D2 along the third direction D3. In some embodiments, all of the first and second upper channel regions 822a-1 and 822a-2, the first and second lower channel regions 822b-1 and 822b-2 and the first and second intergate insulators 832a and 832b may have an equal width in the second direction D2, as illustrated in FIG. 8. Side surfaces of the first upper channel regions 822a-1 may be in the same plane with side surfaces of the first lower channel regions 822b-1 and the first intergate insulator 832a and may be aligned with those side surfaces of the first lower channel regions 822b-1 and the first intergate insulator 832a along the third direction D3. A cross-sectional view of the fourth integrated circuit device 8000 taken along the line A-A′ in FIG. 1 may be similar to that illustrated in FIG. 2. The first and second lower channel region 822b-1 and 822b-2, the first and second upper channel region 822a-1 and 822a-2 and the first and second intergate insulator 832a and 832b may include materials the same as or similar to those of the lower channel region 122b, the upper channel region 122a and the intergate insulator 132 of the first integrated circuit device 2000.

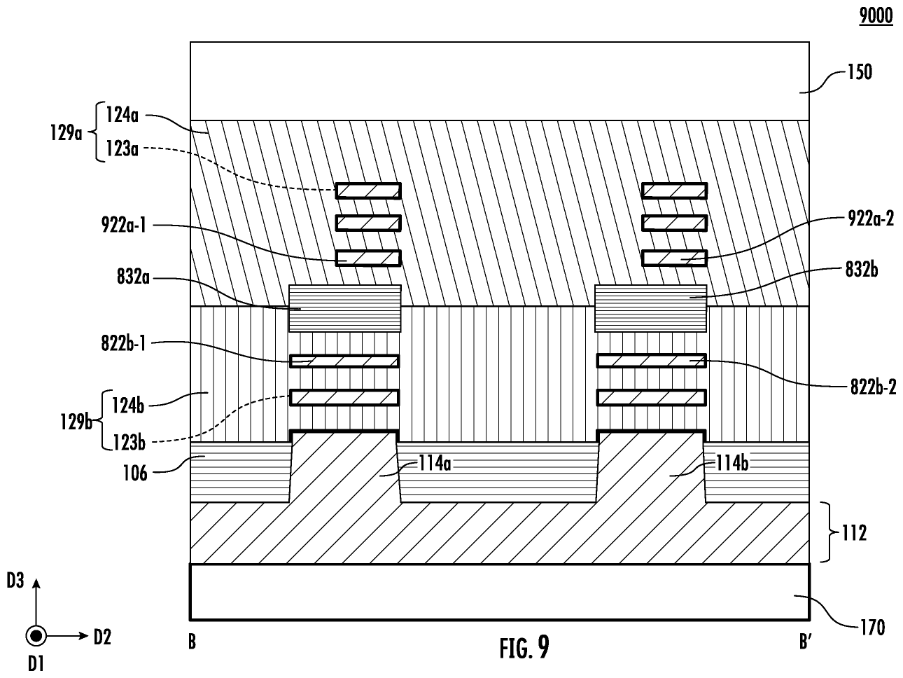

FIG. 9 is a cross-sectional view of a fifth integrated circuit device 9000 taken along the line B-B′ in FIG. 1 according to some embodiments. Referring to FIG. 9, the fifth integrated circuit device 9000 may be similar to the fourth integrated circuit device 8000. The fifth integrated circuit device 9000 may be different from the fourth integrated circuit device 8000, in that first and second upper channel regions 922a-1 and 922a-2 may include respective side surfaces that are not in the same plane with side surfaces of the first and second lower channel regions 822b-1 and 822b-2 and the first and second intergate insulator 832a and 832b, and the upper channel regions 922a-1 and 922a-2 may have a width in the second direction D2 narrower than a width of the upper channel regions 822a-1 and 822a-2 of the fourth integrated circuit device 8000 in the second direction D2. A cross-sectional view of the fifth integrated circuit device 9000 taken along the line A-A′ in FIG. 1 may be similar to that illustrated in FIG. 2. The first and second upper channel regions 922a-1 and 922a-2 may include a material the same as or similar to the upper channel regions 122a of the first integrated circuit device 2000.

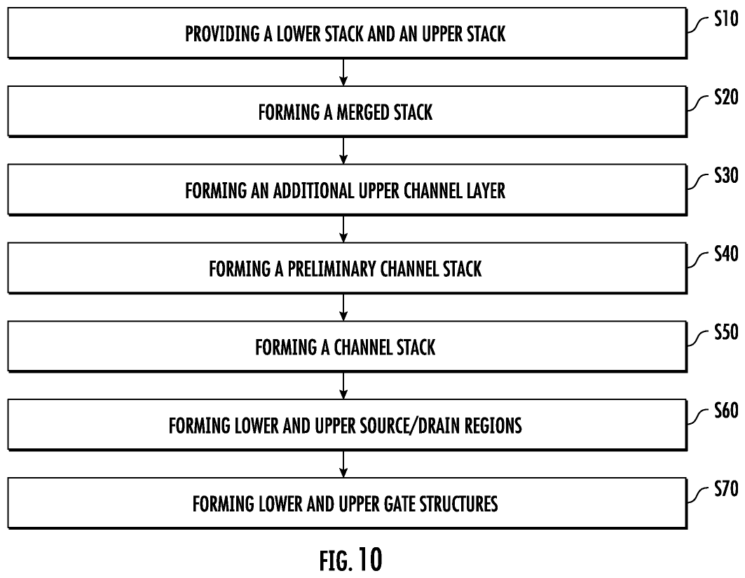

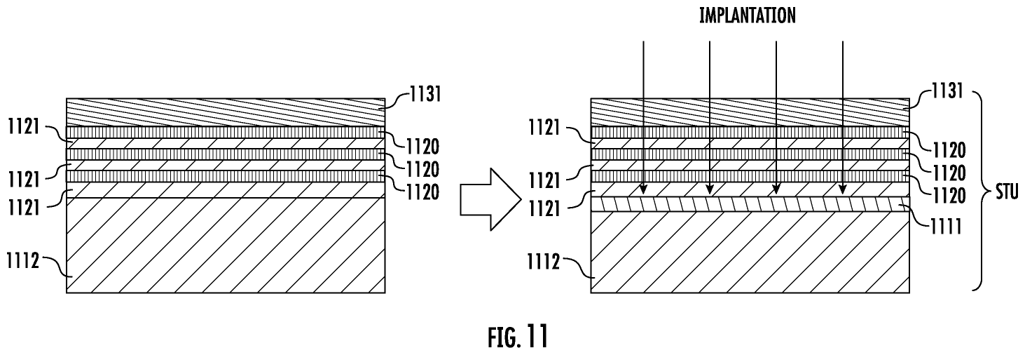

FIG. 10 is a flow chart of a method of forming an integrated circuit device according to some embodiments, and FIGS. 11 through 22 are cross-sectional views illustrating a method of forming an integrated circuit device according to some embodiments. Specifically, FIGS. 11 through 22 illustrate a method of forming the first integrated circuit device 2000 according to some embodiments.

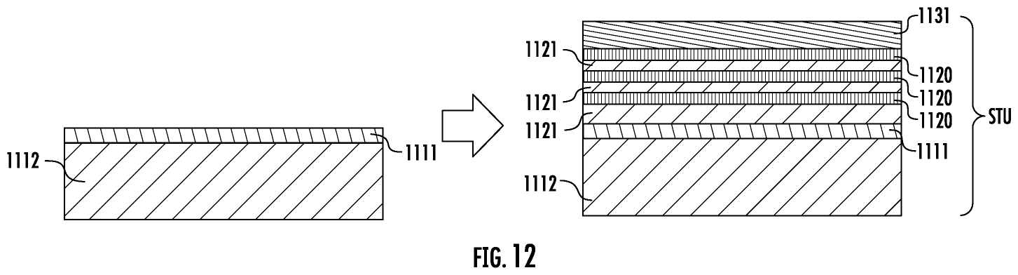

Referring to FIGS. 11 and 12, an upper stack STU may be formed by processes illustrated in FIG. 11 or FIG. 12. Referring to FIG. 11, an upper stack STU may be formed by forming upper channel layers 1121, upper sacrificial layers 1120 that are alternately stacked with the upper channel layers 1121 and an upper intergate insulator layer 1131 on an upper substrate 1112 and then performing an ion implantation process to form a separation layer 1111. The ion implantation process may implant ions (e.g., hydrogen ions) into a portion of the upper substrate 1112, and thus the separation layer 1111 may include those implanted ions.

Referring to FIG. 12, the upper stack STU may be formed by forming the separation layer 1111 through, for example, a deposition process on the upper substrate 1112, and then the upper channel layers 1121, the upper sacrificial layers 1120 and the upper intergate insulator layer 1131 may be formed on the separation layer 1111. The separation layer 1111 may include, for example, SiN, SiBCN, SiOCN, SiBN, SiCN, SiO and/or SiON.

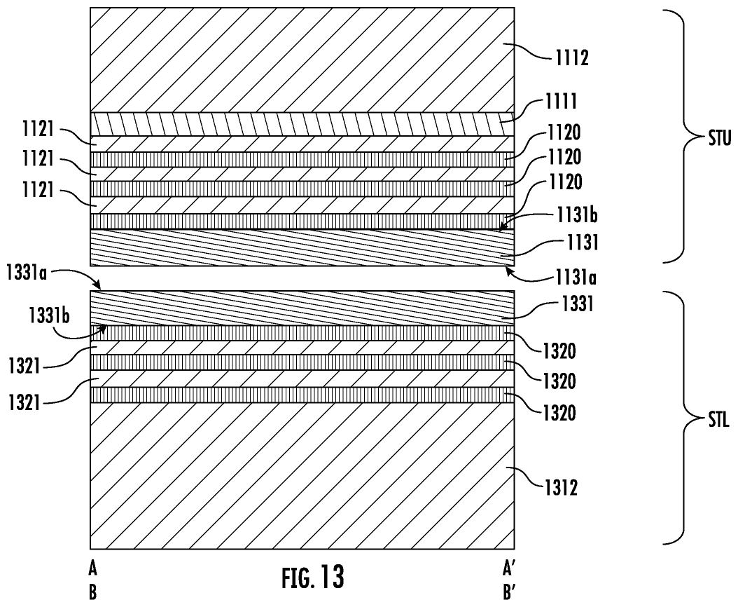

Referring to FIGS. 10 and 13, the method may include providing a lower stack STL and the upper stack STU (Block S10). The upper intergate insulator layer 1131 may include a lower surface 1131b facing the upper substrate 1112 and an upper surface 1131a opposite the lower surface 1131b. The lower stack STL may include a lower substrate 1312, a lower intergate insulator layer 1331 on the lower substrate 1312, lower channel layers 1321 between the lower substrate 1312 and the lower intergate insulator layer 1331 and lower sacrificial layers 1320 stacked alternately with the lower channel layers 1321. The lower intergate insulator layer 1331 may include a lower surface 1331b facing the lower substrate 1312 and an upper surface 1331a opposite the lower surface 1331b.

The lower sacrificial layers 1320 and the upper sacrificial layers 1120 may include a material having an etch selectivity with respect to the lower and upper channel layers 1321 and 1121. The lower and upper sacrificial layers 1320 and 1120 may include, for example, semiconductor material(s) (e.g., Si, Ge, SiGe, GaP, GaAs, SiC, SiGeC and/or InP). In some embodiments, the lower and upper sacrificial layers 1320 and 1120 may include a SiGe layer.

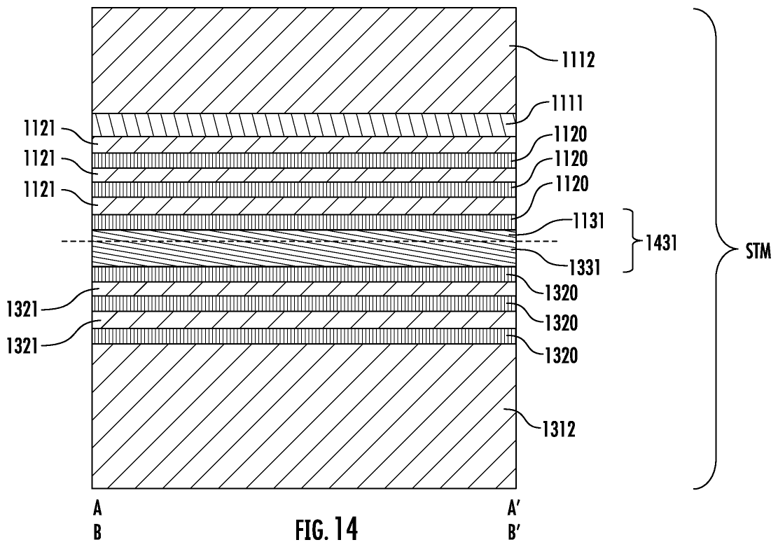

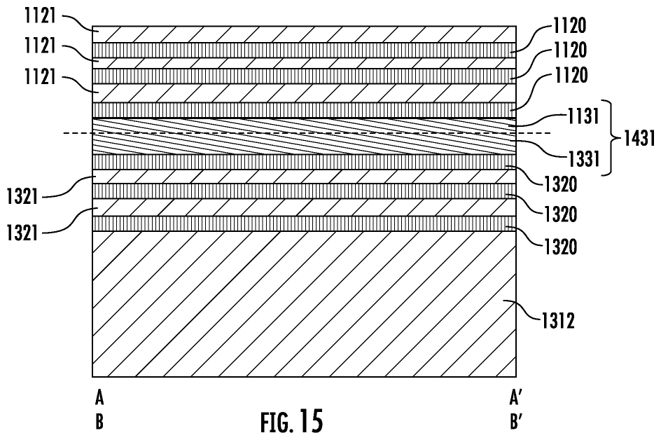

Referring to FIGS. 10 and 14, the method may include forming a merged stack STM by attaching the upper surface 1131a of the upper intergate insulator layer 1131 to the upper surface 1331a of the lower intergate insulator layer 1331 (Block S20). An intergate insulator layer 1431 including the upper intergate insulator layer 1131 and the lower intergate insulator layer 1331 may be formed. Referring to FIG. 15, the upper substrate 1112 and the separation layer 1111 may be removed. When the separation layer 1111 is formed by the ion implantation process illustrated in FIG. 11, the upper substrate 1112 and the separation layer 1111 may be removed by splitting the separation layer 1111 from the upper channel layers 1121. For example, an annealing process may be performed to split the separation layer 1111 from the upper channel layers 1121. When the separation layer 1111 is formed by the process illustrated in FIG. 12, process(es) (e.g., a grinding process, a wet etching process, a dry etching process and/or a Chemical Mechanical Polishing (CMP) process) may be performed to remove the upper substrate 1112 and the separation layer 1111, and the separation layer 1111 may be used as an etch stop layer while removing the upper substrate 1112.

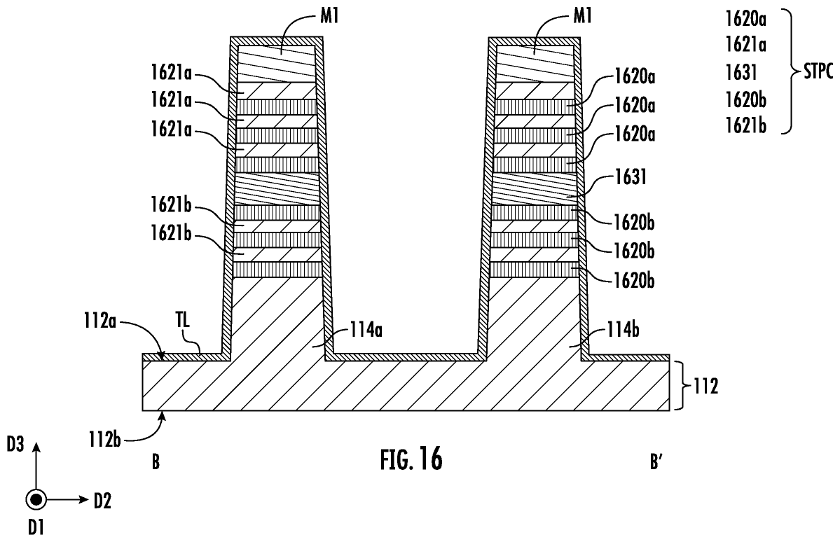

Referring to FIGS. 10 and 16, a preliminary channel stack STPC may be formed (S40). The preliminary channel stack STPC may be formed by forming a first mask layer M1 extending in the first direction D1 and then etching the stack illustrated in FIG. 15 using the first mask layer M1 an etch mask until the lower substrate 1312 is exposed. An upper portion of the lower substrate 1312 may be also etched, thereby semiconductor regions 114 (e.g., the first and second semiconductor regions 114a and 114b) and a substrate 112 may be formed. The preliminary channel stack STPC may include an upper sacrificial pattern 1620a, an upper channel pattern 1621a, an intergate insulator pattern 1631, a lower sacrificial pattern 1620b, a lower channel pattern 1621b. In some embodiments, a trench liner TL may be formed on the preliminary channel stack STPC, the semiconductor regions 114 and the substrate 112. The trench liner TL may include, for example, SiN, SiBCN, SiOCN, SiBN, SiCN, SiO and/or SiON and may have a uniform thickness along surfaces of the preliminary channel stack STPC, the semiconductor regions 114 and the substrate 112.

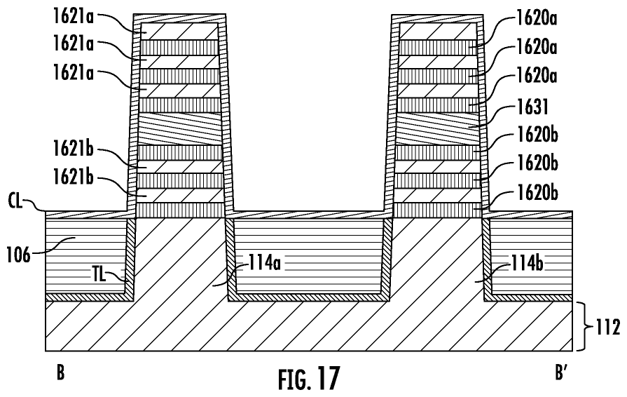

Referring to FIG. 17, the first mask layer M1 may be removed and then a trench isolation layer 106 may be formed on side surfaces of the semiconductor regions 114. An upper portion of the trench liner TL may be removed after the trench isolation layer 106 is formed. In some embodiments, a channel stack liner CL may be formed on the preliminary channel stack STPC. The channel stack liner CL may include, for example, SiN, SiBCN, SiOCN, SiBN, SiCN, SiO and/or SiON and may have a uniform thickness along the surface of the preliminary channel stack STPC.

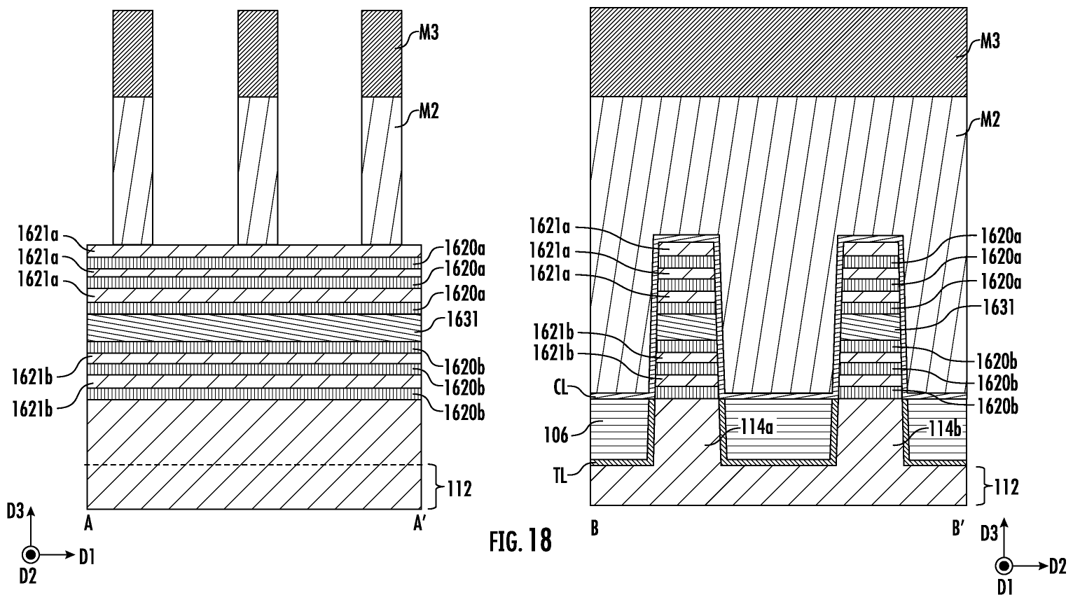

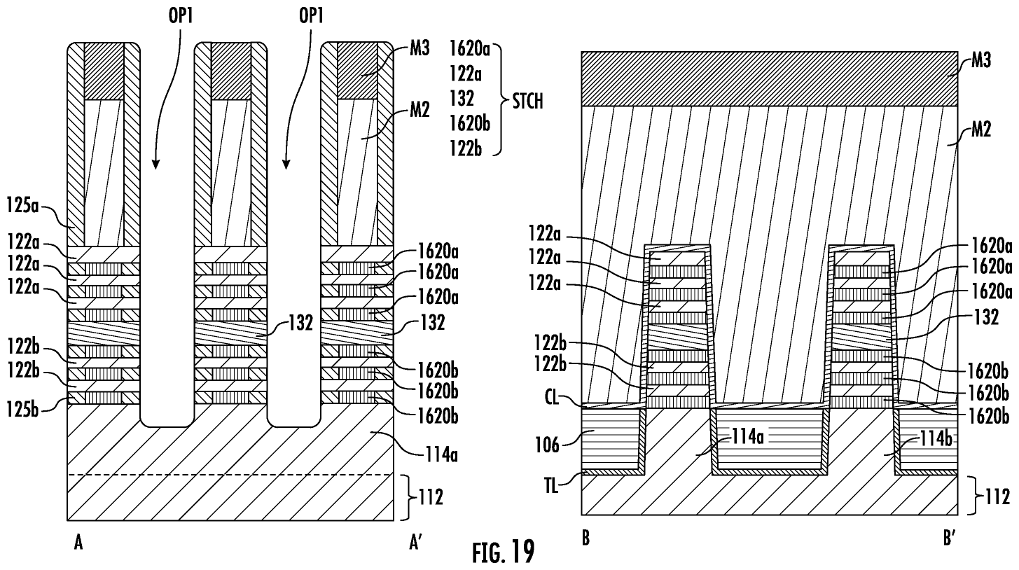

Referring to FIGS. 10, 18 and 19, a channel stack STCH may be formed (Block S50). Referring to FIG. 18, second and third mask layers M2 and M3 extending the second direction D2 may be formed on the structure illustrated in FIG. 17. Referring to FIG. 19, the channel stack STCH may be formed by etching the preliminary channel stack STPC using the second and third mask layers M2 and M3 as an etch mask. The channel stack STCH may include an upper sacrificial pattern 1620a, an upper channel region 122a, an intergate insulator 132, a lower sacrificial pattern 1620b, a lower channel region 122b. In some embodiments, an upper portion of the upper insulating spacer 125a may be formed on side surfaces of the second and third mask layers M2 and M3 before etching the preliminary channel stack STPC and may be also used as an etch mask while etching the preliminary channel stack STPC. Lower insulating spacer 125b and a lower portion of the upper insulating spacer 125a may be formed and a first opening OP1 may be defined between the channel stacks STCH.

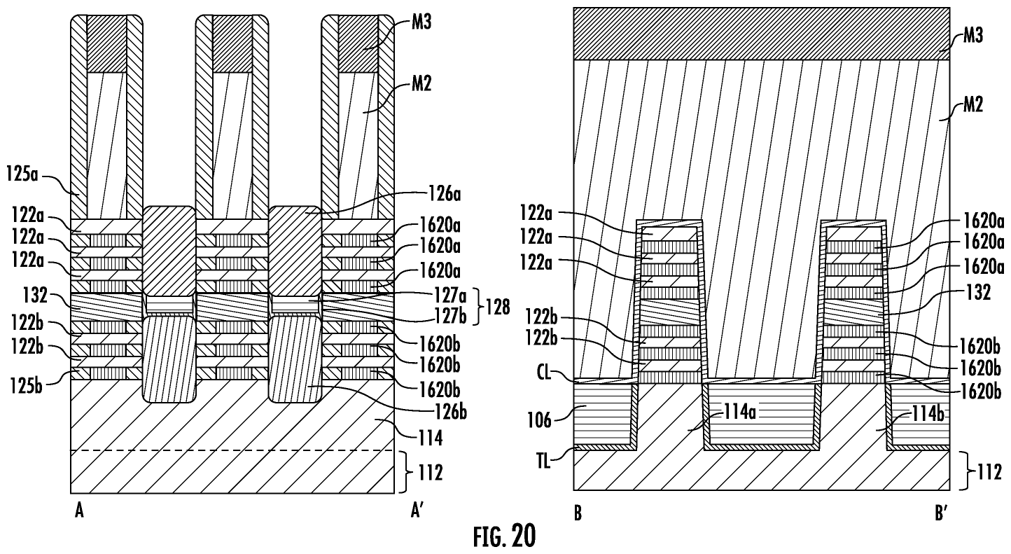

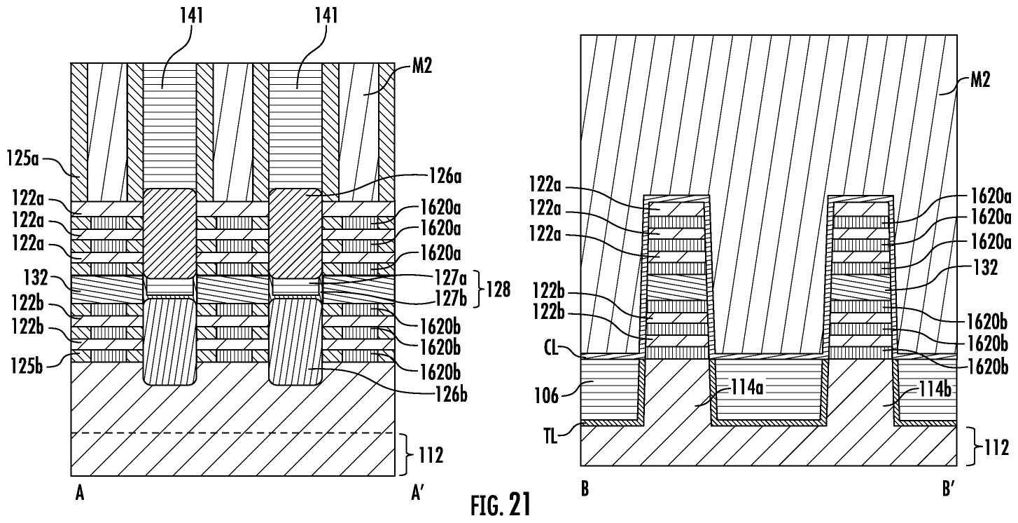

Referring to FIGS. 10 and 20, lower and upper source/drain regions 126b and 126a may be formed (Block S60). For example, the lower source/drain region 126b may be formed by an epitaxial growth process using the lower channel regions 122b as a seed layer, and the upper source/drain region 126a may be formed by an epitaxial growth process using the upper channel regions 122a as a seed layer. In some embodiments, a source/drain insulator 128 may be formed on the lower source/drain region 126b before forming the upper source/drain region 126a. Referring to FIG. 21, an interlayer insulator 141 may be formed on the upper source/drain region 126a. In some embodiments, the third mask layer M3 and an upper portion of the second mask layer M2 may be removed.

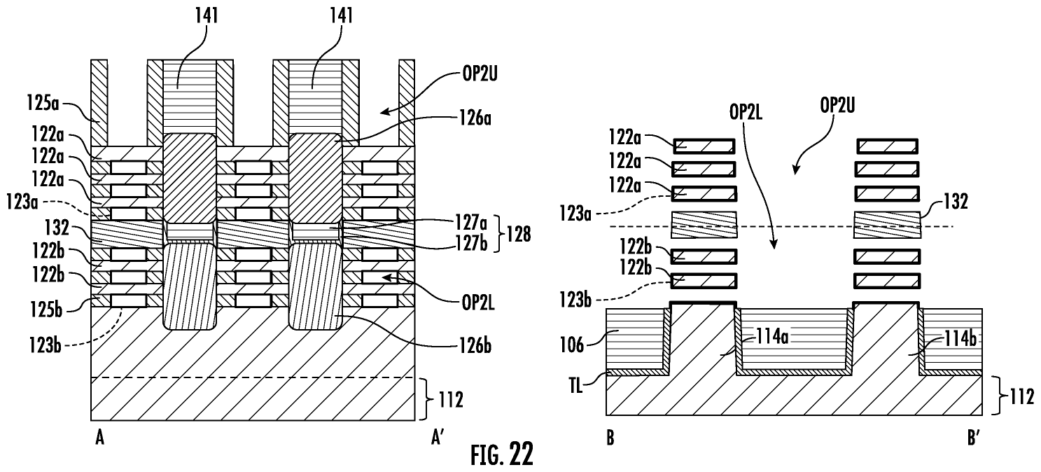

Referring to FIGS. 2, 10 and 22, lower and upper gate structures 129b and 129a may be formed (Block S70). Referring to FIG. 22, the upper sacrificial pattern 1620a and the lower sacrificial pattern 1620b may be removed to expose the lower and upper channel regions 122b and 122a, and then lower and upper gate insulators 123b and 123a may be formed on the lower and upper channel regions 122b and 122a, respectively. The lower gate insulator 123b may defined a lower portion of a second opening OP2L, and the upper gate insulator 123a may define an upper portion of the second opening OP2U. Referring back to FIG. 2, a lower gate electrode 124b may be formed in the lower portion of the second opening OP2L, and an upper gate electrode 124a may be formed in the upper portion of the second opening OP2U.

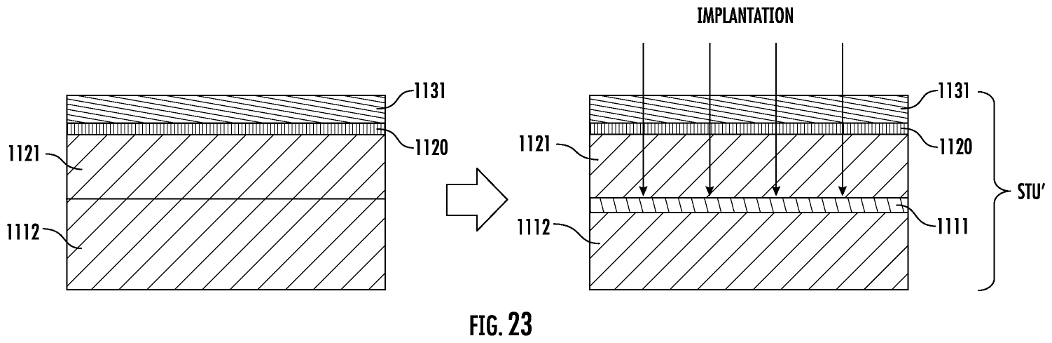

FIGS. 23 through 28 are cross-sectional views illustrating a method of forming an integrated circuit device according to some embodiments. Specifically, FIGS. 23 through 28 illustrate processes performed for Blocks S10, S20 and S30 in FIG. 10.

Referring to FIGS. 10, 23 and 24, an upper stack STU′ may be provided (Block S10). Referring to FIG. 23, the upper stack STU′ may be formed by forming an upper channel layer 1121, an upper sacrificial layer 1120 and an upper intergate insulator layer 1131 on the upper substrate 1112 and then performing an ion implantation process on the upper intergate insulator layer 1131 to form the separation layer 1111 in the upper substrate 1112. The ion implantation process may implant ions (e.g., hydrogen ions) into a portion of the upper substrate 1112.

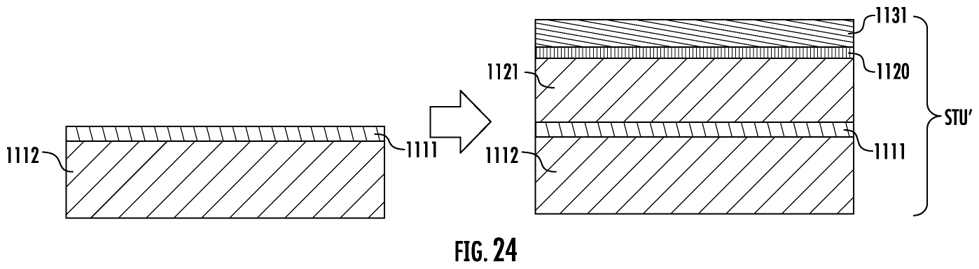

Referring to FIG. 24, the upper stack STU′ may be formed by forming the separation layer 1111 through, for example, a deposition process on the upper substrate 1112, and then forming an upper channel layer 1121, an upper sacrificial layer 1120 and an upper intergate insulator layer 1131 on the separation layer 1111.

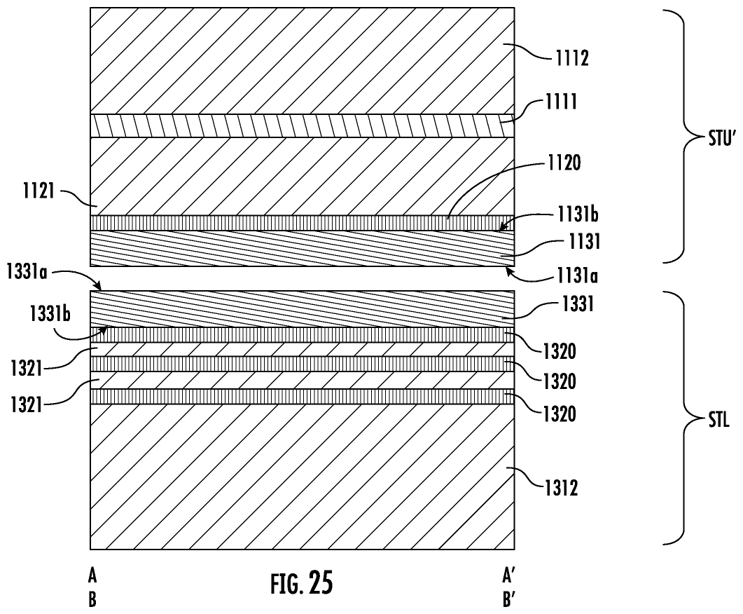

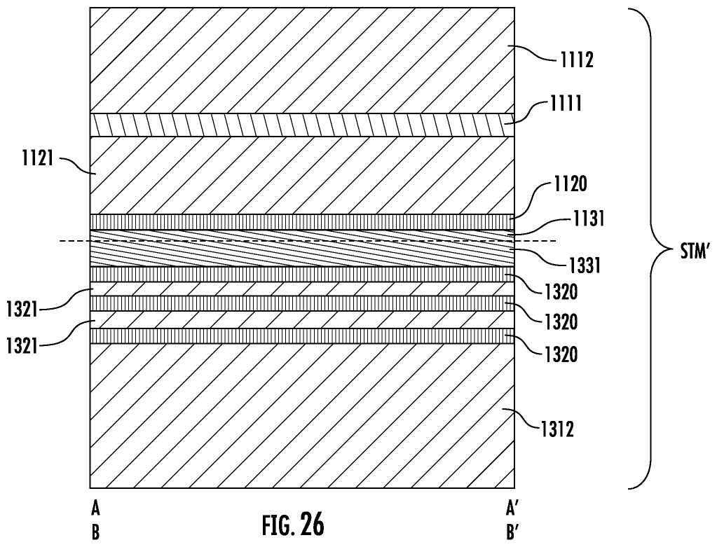

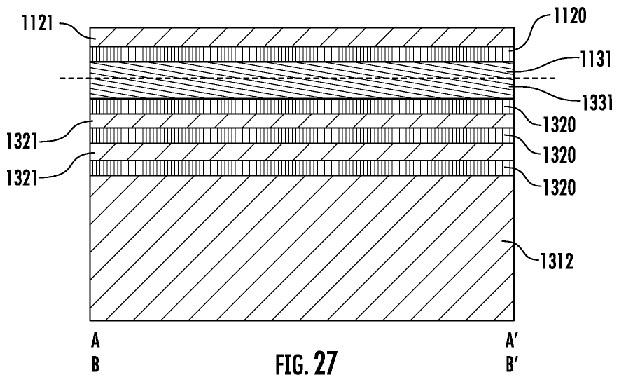

Referring to FIG. 25, the upper stack STU′ may be provided on the lower stack STL. An upper surface 1331a of the upper intergate insulator layer 1131 may face the upper surface 1331a of the lower intergate insulator layer 1331. Referring to FIG. 26, a merged stack STM′ may be formed by attaching the upper surface 1331a of the upper intergate insulator layer 1131 to the upper surface 1331a of the lower intergate insulator layer 1331 (Block S20). Referring to FIG. 27, the upper substrate 1112 and the separation layer 1111 may be removed. When the separation layer 1111 is formed by the ion implantation process illustrated in FIG. 23, the upper substrate 1112 and the separation layer 1111 may be removed by splitting the separation layer 1111 from the upper channel layer 1121. When the separation layer 1111 is formed by the process illustrated in FIG. 24, process(es) (e.g., a grinding process, a wet etching process, a dry etching process and/or a Chemical Mechanical Polishing (CMP) process) may be performed to remove the upper substrate 1112 and the separation layer 1111, and the separation layer 1111 may be used as an etch stop layer while removing the upper substrate 1112. In some embodiments, a portion of the upper channel layer 1121 may also be removed.

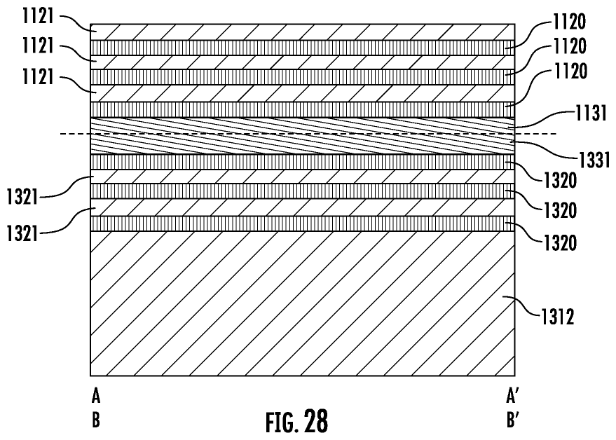

Referring to FIGS. 10 and 28, additional upper channel layers 1121 and additional upper sacrificial layers 1120 may be formed (Block S30) after the upper substrate 1112 and the separation layer 1111 are removed.

It will be understood that the second, third, fourth and fifth integrated circuit devices 5000, 6000, 8000 and 9000 can be formed by methods similar to those described with reference to FIGS. 10-22 with appropriate modifications.

Example embodiments are described herein with reference to the accompanying drawings. Many different forms and embodiments are possible without deviating from the teachings of this disclosure and so the disclosure should not be construed as limited to the example embodiments set forth herein. Rather, these example embodiments are provided so that this disclosure will be thorough and complete, and will convey the scope of the present invention to those skilled in the art. In the drawings, the sizes and relative sizes of layers and regions may be exaggerated for clarity. Like reference numbers refer to like elements throughout.

Example embodiments are described herein with reference to cross-sectional illustrations that are schematic illustrations of idealized embodiments and intermediate structures of example embodiments. As such, variations from the shapes of the illustrations as a result, for example, of manufacturing techniques and/or tolerances, are to be expected. Thus, embodiments herein should not be construed as limited to the particular shapes illustrated herein but may include deviations in shapes that result, for example, from manufacturing. Although an element is illustrated as a single layer in the drawings, that element may include multiple layers.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein, the term “and/or” includes any and all combinations of one or more of the associated listed items. Moreover, the symbol “/” (e.g., when used in the term “source/drain”) will be understood to be equivalent to the term “and/or.”

It will be understood that although the terms “first,” “second,” etc. may be used herein to describe various elements, these elements should not be limited by these terms. These terms are only used to distinguish one element from another. Thus, a first element could be termed a second element without departing from the teachings of the present embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the term “below” can encompass both an orientation of above and below. The device may be otherwise oriented (e.g., rotated 90 degrees or at other orientations) and the spatially relative descriptors used herein may be interpreted accordingly.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

The above-disclosed subject matter is to be considered illustrative, and not restrictive, and the appended claims are intended to cover all such modifications, enhancements, and other embodiments, which fall within the scope of the present invention. Thus, to the maximum extent allowed by law, the scope is to be determined by the broadest permissible interpretation of the following claims and their equivalents, and shall not be restricted or limited by the foregoing detailed description.

What is claimed is:

1. An integrated circuit device comprising:
a first upper channel region on a substrate;
a first lower channel region between the substrate and the first upper channel region;
a first intergate insulator that is between the first lower channel region and the first upper channel region and comprises a lower portion and an upper portion;
an upper gate electrode, wherein the first upper channel region and the upper portion of the first intergate insulator are in the upper gate electrode; and
a lower gate electrode between the substrate and the upper gate electrode, wherein the first lower channel region and the lower portion of the first intergate insulator are in the lower gate electrode.

2. The integrated circuit device of claim 1, wherein the upper gate electrode comprises a lower surface that faces the substrate and contacts the lower gate electrode.

3. The integrated circuit device of claim 1, wherein the upper gate electrode contacts opposing side surfaces of the upper portion of the first intergate insulator.

4. The integrated circuit device of claim 1, wherein the lower gate electrode contacts opposing side surfaces of the lower portion of the first intergate insulator.

5. The integrated circuit device of claim 1, wherein an entirety of the first upper channel region overlaps the first lower channel region.

6. The integrated circuit device of claim 1, wherein a side surface of the first lower channel region and a side surface of the first upper channel region are in the same plane.

7. The integrated circuit device of claim 1, further comprises:
a second upper channel region that is on the substrate and is spaced apart from the first upper channel region in a first direction;
a second lower channel region that is between the substrate and the second upper channel region and is spaced apart from the first lower channel region in the first direction; and
a second intergate insulator that is between the second lower channel region and the second upper channel region and comprises a lower portion and an upper portion,
wherein the second upper channel region and the upper portion of the second intergate insulator are in the upper gate electrode, and
the second lower channel region and the lower portion of the second intergate insulator are in the lower gate electrode.

8. The integrated circuit device of claim 7, wherein each of the first and second intergate insulators comprises a lower surface facing the substrate, and
the lower surfaces of the first and second intergate insulators are equidistant from the substrate.

9. An integrated circuit device comprising:
an upper transistor on a substrate, wherein the upper transistor comprises an upper channel region and an upper source/drain region contacting a side surface of the upper channel region;
a lower transistor between the substrate and the upper transistor, wherein the lower transistor comprises a lower channel region and a lower source/drain region contacting a side surface of the lower channel region; and
an intergate insulator between the upper channel region and the lower channel region, wherein an entirety of the intergate insulator overlaps the lower channel region.

10. The integrated circuit device of claim 9, wherein a side surface of the intergate insulator and the side surface of the upper channel region are in the same plane.

11. The integrated circuit device of claim 9, wherein a side surface of the intergate insulator and the side surface of the lower channel region are in the same plane.

12. The integrated circuit device of claim 9, further comprising a source/drain insulator between the upper source/drain region and the lower source/drain region,
wherein the source/drain insulator comprises a material different from the intergate insulator.

13. The integrated circuit device of claim 12, wherein the source/drain insulator contacts a side surface of the intergate insulator.

14. The integrated circuit device of claim 13, wherein the source/drain insulator comprises an outer layer that contacts the side surface of the intergate insulator and comprises nitrogen.

15. The integrated circuit device of claim 14, wherein the source/drain insulator further comprises an inner layer that comprises a material different from the outer layer, and
the outer layer of the source/drain insulator contacts opposing side surfaces and a lower surface of the inner layer.

16. A method of forming an integrated circuit device, the method comprising:
providing a lower stack comprising a lower substrate, a lower intergate insulator layer on the lower substrate and a lower channel layer between the lower substrate and the lower intergate insulator layer, wherein the lower intergate insulator layer comprises a lower surface facing the lower substrate and an upper surface opposite the lower surface of the lower intergate insulator layer;
providing an upper stack comprising an upper substrate, an upper intergate insulator layer on the upper substrate and an upper channel layer between the upper substrate and the upper intergate insulator layer, wherein the upper intergate insulator layer comprises a lower surface facing the upper substrate and an upper surface opposite the lower surface of the upper intergate insulator layer;
forming a merged stack by attaching the upper surface of the upper intergate insulator layer to the upper surface of the lower intergate insulator layer;
forming a preliminary channel stack by patterning the merged stack, wherein the preliminary channel stack extends in a first direction;
forming a channel stack by patterning the preliminary channel stack, wherein the channel stack comprises an upper channel region, a lower channel region and an intergate insulator that is between the lower channel region and the upper channel region;
forming a lower source/drain region contacting a side surface of the lower channel region; and
forming an upper source/drain region contacting a side surface of the upper channel region.

17. The method of claim 16, wherein the channel stack comprises first and second channel stacks spaced apart from each other in a second direction that is different from the first direction,
the first channel stack comprises a first upper channel region, a first lower channel region, and a first intergate insulator that is between the first lower channel region and the first upper channel region, and
the second channel stack comprises a second upper channel region, a second lower channel region, a second intergate insulator that is between the second lower channel region and the second upper channel region.

18. The method of claim 16, further comprising forming a lower gate electrode and an upper gate electrode,
wherein each of the first and second intergate insulators comprises a lower portion and an upper portion,
the first and second lower channel regions and the lower portions of the first and second intergate insulators are in the lower gate electrode, and
the first and second upper channel regions and the upper portions of the first and second intergate insulators are in the upper gate electrode.

19. The method of claim 16, further comprising:
removing the upper substrate after forming the merged stack and before forming the preliminary channel stack; and then
forming an additional upper channel layer on the upper channel layer,
wherein the upper channel layer is between the upper intergate insulator layer and the additional upper channel layer, and
forming the preliminary channel stack further comprises patterning the additional upper channel layer.

20. The method of claim 16, wherein forming the preliminary channel stack comprises:
forming a mask layer on the merged stack, wherein the mask layer extends in the first direction; and
etching the merged stack using the mask layer as an etch mask until the lower substrate is exposed.
